(19) United States
(12) Patent Application Publication
(10) Pub. No.: US 2007/0262440 A1
(43) Pub. Date: Nov. 15, 2007

(54) Sealing structure and method of manufacturing the sealing structure

(75) Inventor: Nobuyoshi Asaoka, Hachioji-shi (JP)

Correspondence Address: Scully, Scott, Murphy & Presser, 400 Garden City Plaza, Garden City, NY, 11530-3319, US

(73) Assignee: OLYMPUS CORPORATION, Tokyo (JP)

(21) Appl. No.: 11/801,789

(22) Filed: May 11, 2007

(30) Foreign Application Priority Data
May 12, 2006 (JP) 2006-133929

(51) Int. Cl. H01L 23/12

(52) U.S. Cl. 257/704

(57) ABSTRACT

A sealing structure having a sealing space provided by bonding a substrate and an intermediate member with a first bonding part and by bonding the intermediate member and a cap with a second bonding part. The intermediate member has a higher thermal conductivity than the substrate and the cap.

### CROSS-REFERENCE TO RELATED APPLICATIONS

This application is based upon and claims the benefit of priority from prior Japanese Patent Application No. 2006-133929, filed May 12, 2006, the entire contents of which are incorporated herein by reference.

### BACKGROUND OF THE INVENTION

1. Field of the Invention

The present invention relates to a sealing structure for sealing electronic apparatuses, MEMS devices and the like, and to a method of manufacturing the sealing structure.

2. Description of the Related Art

Hitherto, packages each containing a solid-state image sensing device such as a CCD have been sealed airtight, with glass caps composed of a light-transmitting glass plate. Known as a method of sealing such packages with glass caps is the technique disclosed in, for example, Jpn. Pat. Appln. KOKOKU Publication No. 5-37505.

FIG. 14A is a top plan view of the glass cap 100 that constitutes an airtight sealing structure disclosed in Publication No. 5-37505. FIG. 14B is a sectional view of the glass cap 100. As shown in FIGS. 14A and 14B, the glass cap 100 constituting an airtight sealing structure has an adhesive layer 200. To bond the glass cap 100 to a ceramic package (not shown) containing a solid-state image sensing device such as a CCD, the glass cap 100 and the ceramic package are heated in a vacuum and then the adhesive layer 200 is cured, while the adhesive surface of the glass cap 100, including the layer 200, is being pressed to the ceramic package. Further, the adhesive layer 200 is cured while introducing nitrogen gas (N₂).

Thus, the technique disclosed in Publication No. 5-37505 provides an airtight sealing structure.

In the technique disclosed in Publication No. 5-37505, heating is performed in a vacuum. This raises the following problem. Any heating performed in a vacuum can hardly achieve heat convection. It requires much more time than the heating performed in air. That is, with the technique disclosed in Publication No. 5-37505 it is difficult to accomplish tact time shortening. The glass cap 100 may be heated by performing heat conduction using a bonding tool, in order to cure the adhesive layer 200. In this case, heat is applied to the adhesive layer 200 through the glass cap 100. Since the glass cap 100 has low thermal conductivity, it is still difficult to achieve tact time shortening.

### BRIEF SUMMARY OF THE INVENTION

The present invention has been made in view of the foregoing. An object of the invention is to provide a sealing structure and a method of manufacturing the sealing structure. The sealing structure comprises a cap (e.g., component equivalent to the above-mentioned glass cap 100) and a substrate (e.g., component equivalent to the above-mentioned ceramic package), which can be heated and bonded together within a short time, thus accomplishing tact time shortening, even if the heating is performed in a vacuum or if the cap has but low thermal conductivity.

To achieve the object, a sealing structure according to a first aspect of this invention has a sealing space provided by bonding a substrate and an intermediate member with a first bonding part and by bonding the intermediate member and a cap with a second bonding part. The sealing structure is characterized in that the intermediate member has a higher thermal conductivity than the substrate and the cap.

To achieve the object, a method of manufacturing a sealing structure as described in the first aspect of this invention, according to a second aspect of the present invention, is characterized by comprising: a bonding step of bonding the cap, with a second bonding part, to a member which has been made by bonding a substrate and an intermediate member with a first bonding part.

To achieve the object, a method of manufacturing a sealing structure as described in the first aspect of this invention, according to a third aspect of this invention, is characterized by comprising: a bonding step of bonding a substrate, with a first bonding part, to a member which has been made by bonding a cap and an intermediate member with a second bonding part.

To achieve the object, a method of manufacturing a sealing structure as described in the first aspect of this invention, according to a fourth aspect of this invention, is characterized by comprising a bonding step of bonding the substrate and the intermediate member with the first bonding part and bonding the intermediate member and the cap with the second bonding part.

The present invention can provide a sealing structure and a method of manufacturing the sealing structure. The sealing structure comprises a cap and a substrate which can be heated and bonded together within a short time, thus accomplishing tact time shortening, even if the heating is performed in a vacuum or if the cap has but low thermal conductivity.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing a sealing structure according to a first embodiment of the present invention;

FIG. 2A is a diagram explaining step 1-1 of a method of manufacturing the sealing structure according to the first embodiment of the invention;

FIG. 2B is a diagram explaining step 1-2 of the method of manufacturing the sealing structure according to the first embodiment of the invention;

FIG. 2C is a diagram explaining step 1-3 of a method of manufacturing the sealing structure according to the first embodiment of the invention;

FIG. 3 is a sectional view showing a sealing structure according to a second embodiment of the present invention;

FIG. 4 is a diagram explaining step 2-3 of a method of manufacturing the sealing structure according to a second embodiment of the present invention;

FIG. 5 is a sectional view showing a sealing structure according to a third embodiment of the present invention;

FIG. 6A is a diagram explaining step 3-1 of a method of manufacturing the sealing structure according to the third embodiment of the invention;

FIG. 6B is a diagram explaining step 3-2 of a method of manufacturing the sealing structure according to the third embodiment of the invention;

FIG. 6C is a diagram explaining step 3-3 of a method of manufacturing the sealing structure according to the third embodiment of the invention;

FIG. 7A is a diagram explaining step 4-1 of a method of manufacturing the sealing structure according to a fourth embodiment of the present invention;

FIG. 7B is a diagram showing the positional relationship that the components have immediately before step 4-2 of the method of manufacturing the sealing structure according to the fourth embodiment of the invention;

FIG. 7C is a diagram explaining step 4-2 of a method of manufacturing the sealing structure according to the fourth embodiment of the invention;

FIG. 8 is a sectional view showing a sealing structure according to a third modification of the present invention;

FIG. 9 is another sectional view showing the sealing structure according to a third modification of the present invention;

FIG. 10 is a diagram explaining a step of manufacturing the sealing structure according to a third modification of the present invention;

FIGS. 11A and 11B are sectional views showing a sealing structure according to a ninth modification of the present invention;

FIGS. 12A and 12B are sectional views showing a sealing structure according to a tenth modification of the present invention;

FIG. 13 is a sectional view showing a sealing structure according to an eleventh modification of the present invention;

FIG. 14A is a top plan view of the glass cap of the airtight sealing structure disclosed in Jpn. Pat. Appln. KOKOKU Publication No. 5-37505; and

FIG. 14B is a side view of the glass cap shown in FIG. 14A.

### DETAILED DESCRIPTION OF THE INVENTION

Embodiments of a sealing structure according to this invention will be described, with reference to the accompanying drawings.

### First Embodiment

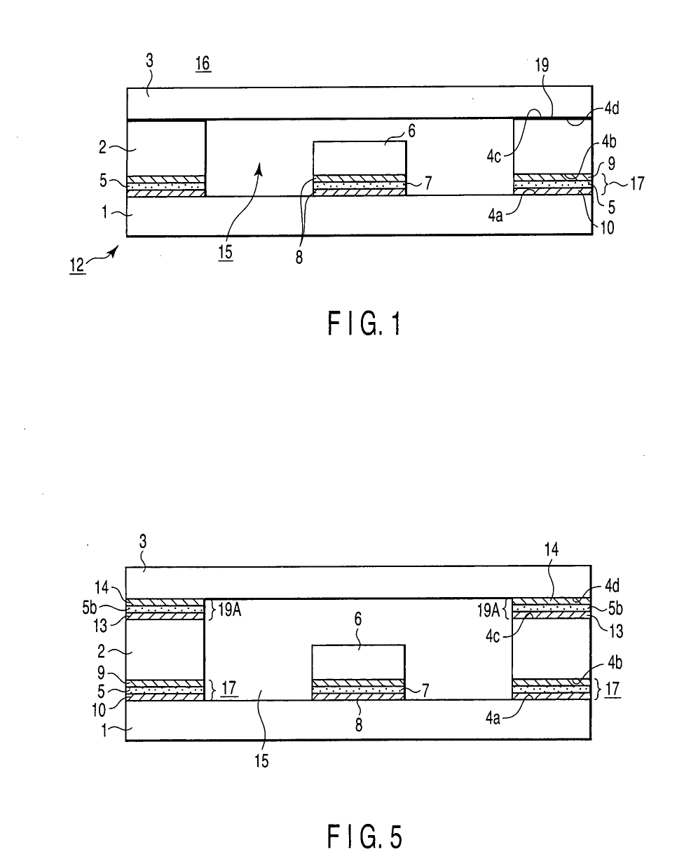

FIG. 1 is a sectional view showing a sealing structure according to the first embodiment of the present invention. As shown in FIG. 1, in the first embodiment, a substrate 1 and an intermediate member 2 (a component which characterizes this invention and will be described later in detail) are bonded together, and the intermediate member 2 and a cap 3 are bonded together, in the first embodiment. A sealing space 15 is thereby formed, in which a device 6 (e.g., a small light deflector).

To bond the device 6 and the substrate 1 with a solder layer 7, a die-bonding thin film 8 is formed on that surface of the substrate 1 and device 6, which will contact when the substrate 1 and device 6 are bonded. In other words, the device 6 is bonded to the substrate 1 in the sealing space 15, by using the solder layer 7 and die-bonding thin film 8. In the first embodiment, the device 6 is sealed in the sealing space 15, which is an atmosphere at a pressure lower than the atmospheric pressure (hereinafter referred to as a “vacuum”). That is, the sealing space 15 is held in a vacuum. Nonetheless, the pressure in the sealing space 15 is not limited to a vacuum.

The substrate 1 and the intermediate member 2 are bonded, with a first bonding part 17 interposed between them. The intermediate member 2 and the cap 3 are bonded, with a second bonding part 19 interposed between them. The first bonding part 17 and the second bonding part 19 will be described below.

The first bonding part 17 comprises a first metal thin film 9, a second metal thin film 10, and a solder layer 5. The first metal thin film 9 and the second metal thin film 10 serve to bond the substrate 1 and the intermediate member 2 to each other. The first metal thin film 9 has been formed on the bonding surface 4b of the intermediate member 2, by performing an ordinary semiconductor process. Similarly, the second metal thin film 10 has been formed on the bonding surface 4a of the substrate 1, by performing an ordinary semiconductor process. The first and second metal thin films 9 and 10 are films firmly bonded together with the solder layer 5, thus bonding the substrate 1 and the intermediate member 2 to each other (thereby to provide a sealing structure 12).

The intermediate member 2 may be, for example, a metal bulk. In this case, neither the first metal thin film 9 nor the second metal thin film 10 need be formed. Then, a step of forming metal thin films can be dispensed with.

The intermediate member 2 and the first metal thin film 9 or second metal thin film 10 may be made of the same metal. Even in this case, the intermediate member 2 is one component, and the first metal thin film 9 or second metal thin film 10 is another component.

The second bonding part 19 has been formed by performing anodic bonding at the bonding surface 4c of the intermediate member 2 and the bonding surface 4d of the cap 3 that contact each other. To provide the second bonding part 19, the cap 3 is made of glass that can achieve anodic bonding, such as PYREX (registered trademark). The bonding surface 4c of the intermediate member 2 and the bonding surface 4d of the cap 3 can undergo anodic bonding.

Wires (not shown) penetrate the substrate 1, extending from the sealing space 15 into a space 16 outside the sealing structure 12.

The substrate 1, the intermediate member 2 and the cap 3 are made of material that transmits no gas, or material fit for use in forming sealing structures. The intermediate member 2, which is a component that characterizes this invention, is made of material that has higher thermal conductivity than those of the substrate 1 and cap 3.

In the first embodiment, the substrate 1 is made of alumina (thermal conductivity: 21 W·m⁻¹·K⁻¹), the intermediate member 2 is made of silicon (thermal conductivity: 168 W·m⁻¹·K⁻¹), and the cap 3 is made of PYREX® (thermal conductivity: 1.1 W·m⁻¹·K⁻¹)

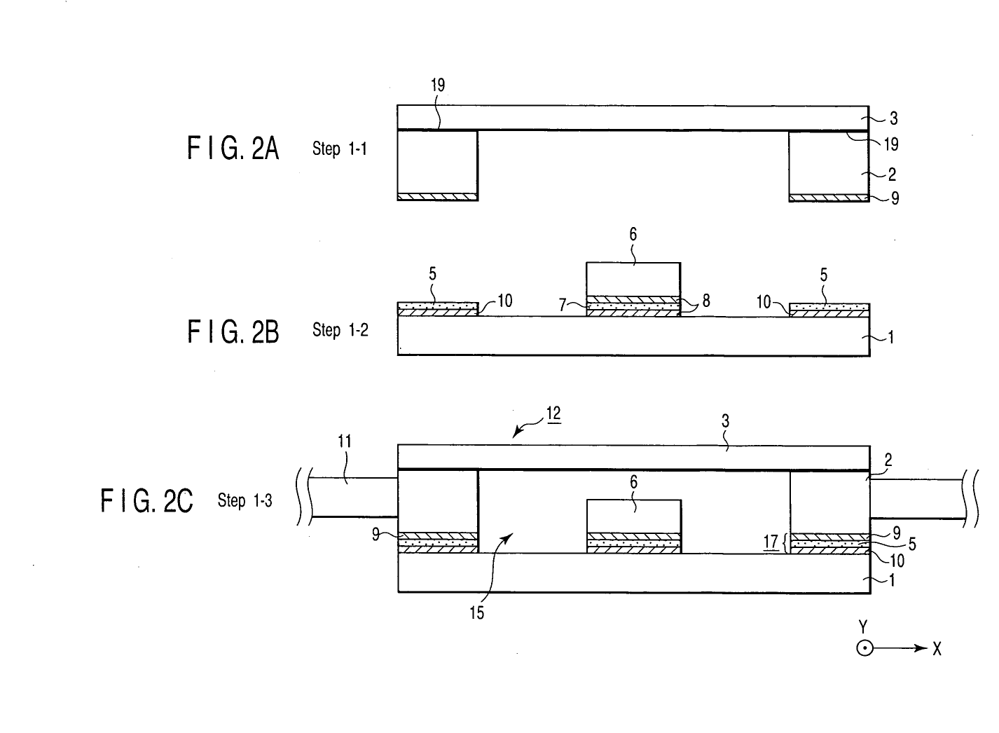

A method of manufacturing the sealing structure 12 according to the first embodiment will be explained, with reference to FIGS. 2A to 2C. Since the configurations of the bonding parts have been described above in detail, the following explanation will center on the sequence of steps of manufacturing the structure 12.

First, as shown in FIG. 2A, the intermediate member 2 having the first metal thin film 9 formed on it and the cap 3 are subjected to anodic bonding (Step 1-1). Next, as shown in FIG. 2B, the device 6 is die-bonded to the substrate 1 having the second metal thin film 10 formed on it (Step 1-2). Then, the substrate 1 and the intermediate member 2 are bonded together with solder layer 5 in a vacuum (Step 1-3).

In Step 1-3, the solder layer 5 is interposed between the first metal thin film 9 and the second metal thin film 10, to make the substrate 1 and the intermediate member 2 firmly contact each other. Thereafter, as shown in FIG. 2C, a bonding tool 11 is set into contact with the intermediate member 2, heating the same. Heat is thereby conducted from the bonding tool 11 via the intermediate member 2 to the first metal thin film 9, solder layer 5 and second metal thin film 10.

Eventually, the solder layer 5 is heated to a temperature higher than its melting point. After the solder layer 5 has melted, the heating the bonding tool 11 performs is stopped. When the temperature of the solder 5 falls below the melting point of solder, the intermediate member 2 is completely bonded to the substrate 1. The sealing structure 12 having the sealing space 15, which is a vacuum, is thus provided.

In the first embodiment, the first bonding part 17 can be heated within a short time as described above in the process of bonding the cap 3 to the substrate 1 to form the sealing structure 12, though the heating is performed in a vacuum and the cap 3 has low thermal conductivity. Thus, the first embodiment can provide a sealing structure that can be manufactured, shortening the tact time in the bonding process, and can provide a method of manufacturing the sealing structure, in which tact time shortening can be accomplished in the bonding process.

More specifically, Step 1-3 described above achieves the following advantages 1 to 3.

(Advantage 1)

The heat generated by the bonding tool 11 is conducted from the intermediate member 2, which has higher thermal conductivity than the substrate 1 and the cap 3, to the first substrate 1 through the first bonding part 17 and to the cap 3 through the second bonding part 19. Nonetheless, the heat is hardly conducted from the bonding tool 11 to the substrate 1 and cap 3, because the substrate 1 and cap 3 have lower thermal conductivity than the intermediate member 2. That is, the heat is readily conducted from the bonding tool 11 to the first bonding part 17 and second bonding part 19. In other words, the heat never propagates to anything other than first and second bonding parts 17 and 19.

Hence, heat is conducted to the first bonding part 17 faster than in the case where the intermediate member 2 is made of alumina (i.e., the material of the substrate 1) or PYREX (i.e., the material of the cap 3), or than in the above-mentioned conventional technique that uses no components equivalent to the intermediate member 2. That is, the first bonding part 17 can be heated to a desired temperature within a shorter time. Since Step 1-3 can be finished in a shorter time, the tact time can be shortened, increasing the productivity and ultimately providing the sealing structure at a lower cost than otherwise.

(Advantage 2)

As described above, heat is hardly conducted from the bonding tool 11 to the substrate 1 because the substrate 1 has lower thermal conductivity than the intermediate member 2. Therefore, the heat is scarcely conducted through the substrate 1 to the device 6. The device 6 is thus prevented from being heated. This resists the degradation of the device 6 in performance, which is caused by the heat applied in the bonding process, even if the device 6 is an electronic device, a MEMS device or the like which may be degraded in performance when heated, or in which the bonding process must be performed at low temperature.

(Advantage 3)

As indicated above, heat is hardly conducted from the bonding tool 11 to the cap 3 because the cap 3 has lower thermal conductivity than the intermediate member 2. Therefore, the cap 3 is scarcely heated. Hence, if an optical thin film or the like that will be degraded in performance when heated is formed on that surface of the cap 3, to which the intermediate member 2 is bonded, its degradation by the heat will be suppressed. In this case, the optical thin film should better be formed after Step 1-1 in which the cap 3 is heated to achieve the anodic bonding.

The present embodiment achieves the following advantage, in addition to the above-mentioned advantages 1 to 3. Since the sealing space 15 is a vacuum, almost no convection takes place in the Step 1-3, and heat transfer by virtue of convection can hardly be expected to occur in the Step 1-3. In spite of this, the first bonding part 17 can be efficiently heated.

If the sealing space 15 is a vacuum, the device 6, e.g., a small light deflector, can be prevented from degrading due to water in air. Further, the attenuation of its resonance can be less prominent than in air. The device 6 can therefore deflect light at a larger angle than in air, when driven with the same force.

Since the cap 3 is made of glass that can transmit light, the device 6 can apply and receive light through the cap 3. Made of glass, the cap 3 can provide, as is desired, the sealing space 15 in which outgas is hardly generated. The solder layer 5 hardly generates outgases when it is heated. Solder is therefore preferred as bonding material for use in forming the sealing space 15.

The substrate 1 is shaped like a flat plate as shown in FIGS. 2A and 2B. In Step 1-2 (FIG. 2B) of die-bonding the device 6 to the substrate 1, the die-bonding tool (not shown) never contact the substrate 1 to render it impossible to mount the device 6 on the substrate 1, even if the die-bonding tool is larger than the substrate 1 in both the X direction and the Y direction. In other words, the size of the die-bonding tool used in Step 1-2 is not limited. That is, the freedom of design for the die-bonding tool is high. Hence, the die-boding tool can be produced at low cost and can be delivered in a short time. This helps to increase the productivity of the sealing structure. Note that the X direction is a left-to-right direction in the plane of the drawing, and the Y direction is a direction perpendicular to the plane of the drawing.

### Second Embodiment

FIG. 3 is a sectional view showing a sealing structure according to the second embodiment of the present invention. This sealing structure differs from the sealing structure according to the first embodiment in that the size L₂ of the intermediate member 2 is greater than the size L₃ of the cap 3. The intermediate member 2 of the sealing structure 12 according to the second embodiment therefore has a part A as shown in FIG. 3, which characterizes the second embodiment.

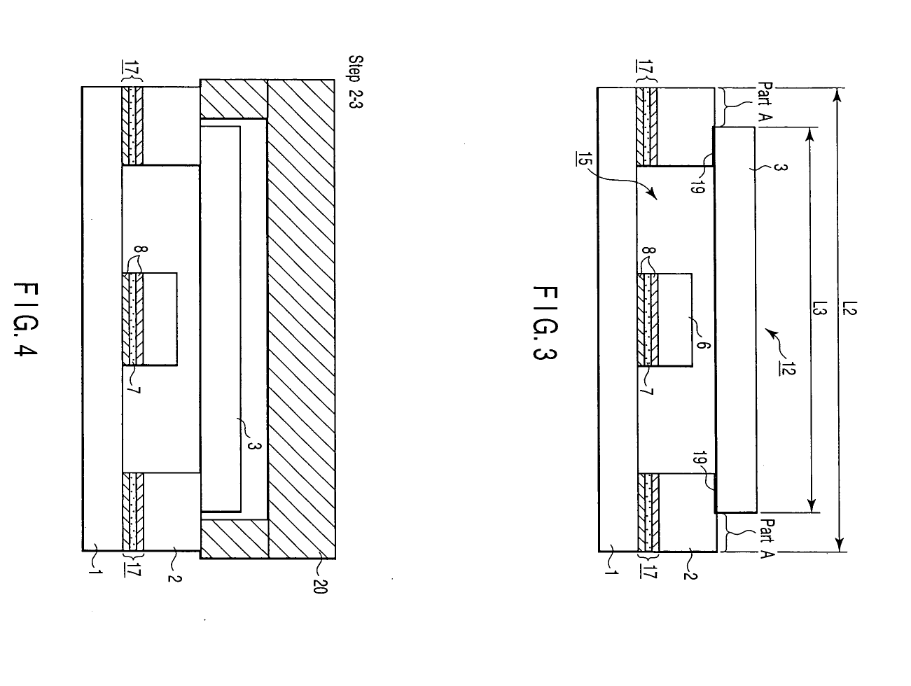

To manufacture the sealing structure 12 according to the second embodiment, Step 2-3 shown in FIG. 4 is performed, instead of Step 1-3 performed in the first embodiment, after Step 1-1 and Step 1-2 identical to those of the first embodiment have been performed. Step 2-3 differs from Step 1-3 in that a bonding tool 20 abuts part A of the intermediate member 2, which projects form the cap 3.

As can be understood form the above, the second embodiment can provide a sealing structure and a method of manufacturing a sealing structure, which can achieve not only the same advantages as the first embodiment, but also the following advantage. That is, the bonding tool 20 can be easily set into contact with the intermediate member 2 by using an ordinary bonding apparatus, because the intermediate member 2 has part A that projects from the form the cap 3.

The term “ordinary bonding apparatus” means an apparatus designed to change, with time, the load which the bonding tool applies (in the gravity-acting direction) to the parts being bonded and the temperature to which the bonding tool heats the parts being bonded.

How the load applied to the parts being bonded and the temperature of the parts being bonded should be changed with time is one of the factors that determine the quality of bonding achieved by soldering.

In the sealing structure and the method of manufacturing a sealing structure, according to the present embodiment, part A of the intermediate member 2 is used as a face which the bonding tool 20 abuts. Therefore, the factor that determines the quality of bonding achieved by soldering can be easily controlled, merely by designing part A, imparting an appropriate width (area) to part A.

The advantage specific to the sealing structure and the method of manufacturing the sealing structure, according to the second embodiment, will be described below in detail.

(Advantage 1)

The ordinary bonding apparatus can easily make the bonding tool 20 abut the intermediate member 2, because the member 2 has part A. Thus, no special apparatuses must be used to make the bonding tool 20 abut the intermediate member 2.

(Advantage 2)

To bond and seal parts together well by soldering as indicated above, thereby to provide a reliable sealing structure, the factor that determines the quality of bonding achieved by soldering is important. Hence, it is desired that the load applied to the parts being bonded and the temperature of the parts being bonded should be changed with time, in the best possible manner. In the second embodiment, the bonding tool 20 heats and presses part A, thus easily and accurately controlling the temperature of the parts being bonded and the load applied to these parts by using the above-defined ordinary apparatus. The second embodiment can therefore provide a reliable sealing structure composed of parts well bonded and sealed together by soldering, and a method of manufacturing such a sealing structure.

(Advantage 3)

As described in regard to advantage 2, a reliable sealing structure composed of parts well bonded and sealed together by soldering can be provided by optimally controlling the load applied to the parts being bonded and the temperature to which the parts are heated. To attain advantage 2, the means for bonding the parts is not limited to soldering. Instead of solder, thermosetting resin, glass frit or the like may be used to bond the parts. In this case, too, it is desirable to change, with time, the load which is applied to the parts being bonded and the temperature to which the parts are heated, in the best possible manner. This can be accomplished in the second embodiment.

(Advantage 4)

If the amount of heat conducted from the bonding tool 20 to the unit width (unit area) of part A is constant, the amount of heat conducted per unit time to the parts being bonded can be changed by changing the width (area) of part A. Thus, this amount of heat can be increased by increasing the width of part A. Hence, part A serves to heat the parts being bonded to a desired temperature within a desired time even if the area in which the bonding tool 20 should abut one surface (side) of the intermediate member 2 is smaller than the area required to achieve desirable conduction of heat. That is, the parts being bonded can be heated to the desired temperature within the desired time. The bonding step can thereby be completed in a short time, without the necessity of increasing the amount of heat conducted to the unit area of part A, by improving the performance of the ordinary bonding apparatus. Thus, the tact time can be shortened and the productivity is raised, ultimately providing the sealing structure at a lower cost than otherwise. Moreover, the load which is applied to the parts being bonded and the temperature to which the parts are heated can be changed with time over a broader range, only by setting the width (area) of part A to an appropriate value.

### Third Embodiment

FIG. 5 is a diagram showing a sealing structure according to the third embodiment of the present invention. This sealing structure differs from the sealing structure according to the first embodiment in the following three respects.

### (1) A third metal thin film 13 is formed on the bonding surface 4c of the intermediate member 2. Note that the third metal thin film 13 is identical to the first metal thin film 9 in terms of configuration and function.

### (2) A fourth metal thin film 14 is formed on the bonding surface 4d of the cap 3. Note that the fourth metal thin film 14 is identical to the first metal thin film 9 in terms of configuration and function.

### (3) A solder layer 5b bonds the third metal thin film 13 and the fourth metal thin film 14, whereby the cap 3 is bonded to the intermediate member 2.

The bonding part constituted by the solder layer 5b, third metal thin film 13 and fourth metal thin film 14 corresponds to the second bonding part 19 of the first and second embodiments. Therefore, the bonding part will be referred to hereinafter as the “second bonding part 19A.”

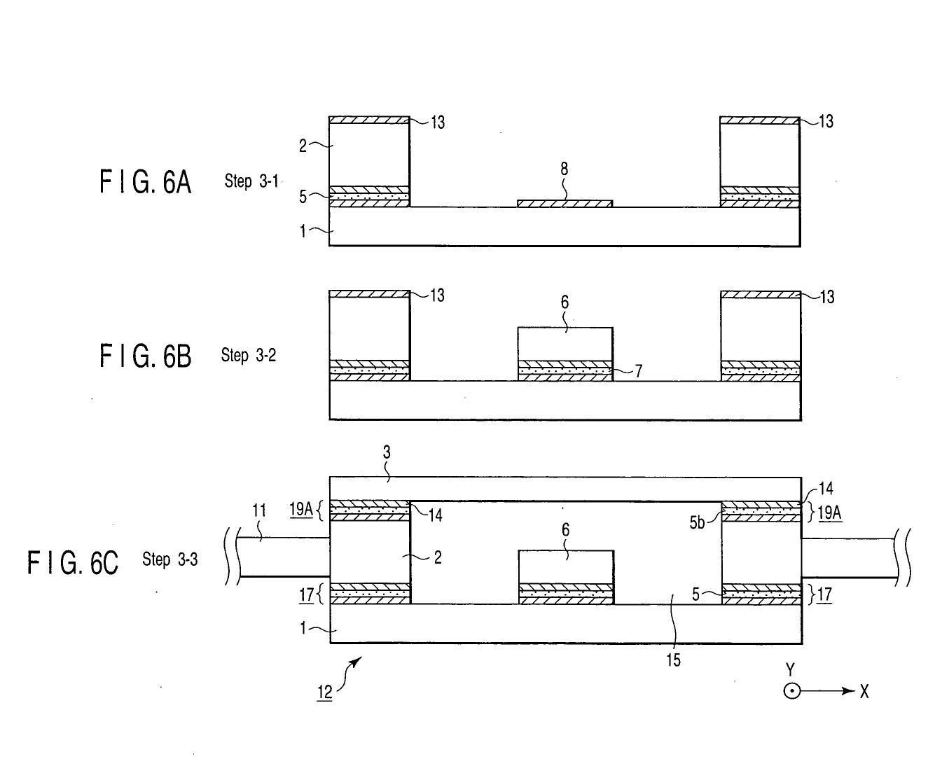

A method of manufacturing the sealing structure according to the third embodiment will be explained, with reference to FIGS. 6A to 6C. Since the configurations of the bonding parts have been described above in detail, the following explanation will center on the sequence of steps of manufacturing the sealing structure according to the this embodiment.

First, as shown in FIG. 6A, the substrate 1 and the intermediate member 2 having the third metal thin film 13 formed on it are bonded with the solder layer 5 (Step 3-1). Next, as shown in FIG. 6B, the device 6 is die-bonded to the substrate 1, by using a solder layer 7 (Step 3-2). Then, as shown in FIG. 6C, the cap 3 having the fourth metal thin film 14 on it is bonded to the intermediate member 2 in a vacuum, by using the solder layer 5b (Step 3-3). Thus, a sealing structure 12 having a sealing space 15 that is a vacuum is provided in Step 3-3.

As set forth above, the third embodiment can provide a sealing structure and a method of manufacturing a sealing structure, which achieve the following advantages.

First, the third embodiment can provide a sealing structure and a method of manufacturing a sealing structure, which attain the same advantages as the first embodiment, including advantages 1 to 3 achieved in Step 1-3 of the first embodiment.

Second, the third embodiment can provide a sealing structure and a method of manufacturing a sealing structure, in which the second bonding part 19A can be efficiently heated, though the substrate 1 and the cap 3 must be bonded in a vacuum, or in the sealing space 15, and no heat transfer by virtue of convection can therefore be expected to occur in the sealing space 15.

In the third embodiment, the cap 3 and the device 6 never contact when they are aligned with each other in both the X direction and the Y direction (see FIG. 6C) in order to bond the cap 3 to the intermediate member 2. This is because of the intermediate member 2. Thus, in the third embodiment, the device 6 is prevented from being damaged, without using any special apparatuses. Note that the X direction is a left-to-right direction in the plane of the drawing, and the Y direction is a direction perpendicular to the plane of the drawing.

The solder layer 5 bonding the substrate 1 and the intermediate member 2 and the solder layer 5b bonding the substrate 1 and the cap 3 are made of different solder alloys. This brings forth the following advantage.

More precisely, the solder layer 5 bonding the substrate 1 and the intermediate member 2 is made of a solder alloy that has a higher melting point than the solder alloy of the solder layer 5b bonding the substrate 1 and the cap 3. Therefore, the solder layer 5 that has bonded the substrate 1 and the intermediate member 2 in Step 3-1 can be prevented from melting in Step 3-3.

The substrate 1 and the intermediate member 2 need not be bonded in the same way as the intermediate member 2 and the cap 3 are bonded. They can be bonded in any other way only if they can define the above-mentioned sealing space 15.

### Fourth Embodiment

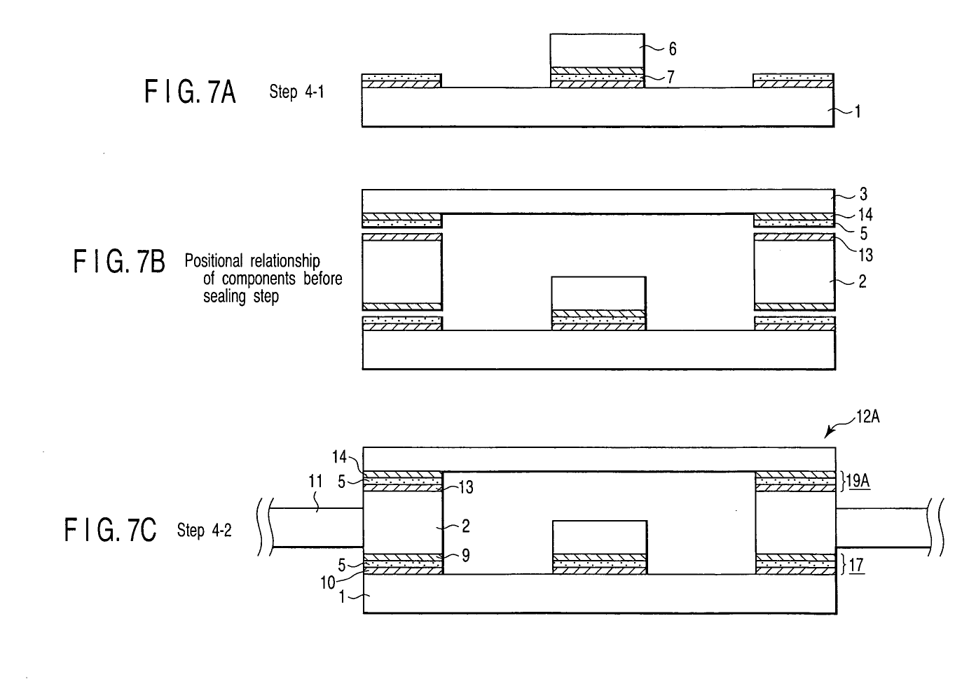

A method of manufacturing a sealing structure according to the fourth embodiment will be explained, with reference to FIGS. 7A to 7C. Note that the sealing structure according to the fourth embodiment is identical in configuration to the sealing structure according to the third embodiment, though it is manufactured by a different method.

First, as shown in FIG. 7A, the substrate 1 and the device 6 are bonded with the solder layer 7 (Step 4-1). Next, as shown in FIG. 7C, the substrate 1 having the second metal thin film 10 formed on it, the intermediate member 2 having the first metal thin film 9 and the third metal thin film 13 formed on it, and the cap 3 having the fourth metal thin film 14 formed on it are made to contact one another in a vacuum and bonded together with solder layers 5, with the bonding tool 11 set in contact with the intermediate member 2 (Step 4-2). Thus, the sealing structure 12A according to the third embodiment is provided. Note that before the substrate 1, intermediate member 2 and the cap 3 are bonded together in Step 4-2, they have such a positional relationship as illustrated in FIG. 7B.

As described above, the fourth embodiment can not only achieve not only the same advantages as the third embodiment, but also provide the sealing structure by performing less steps than in the third embodiment.

This invention is not limited to the first to fourth embodiments described above. Various changes and modifications can of course be made within the scope and spirit of the invention. Some modifications will be described, with reference to the drawings.

[First Modification]

In any embodiment described above, the substrate 1, intermediate member 2 and the cap 3 may be made of materials that have almost the same coefficient of linear expansion. If this is the case, the sealing structure 12 will hardly be distorted when the substrate 1, intermediate member 2 and the cap 3 are heated in the bonding step.

Two examples of the combination of materials for the substrate 1, intermediate member 2 and the cap 3 will be specified below.

### Example 1 of Material Combination

### 1. Material of the Intermediate Member 2

Silicon (Si) (thermal conductivity: 168 W·m⁻¹·K⁻¹; coefficient of linear expansion: 3.5×10⁻⁶ K⁻¹0-227° C.)

### 2. Material of the Substrate 1 and Cap 3

PYREX (thermal conductivity: 1.1 W·m⁻¹·K⁻¹; coefficient of linear expansion: 3.25×10⁻⁶ K⁻¹ 0-300° C.)

### Example 2 of Material Combination

### 1. Material of the Intermediate Member 2

Kovar (thermal conductivity: 19.7 W·m⁻¹·K⁻¹; coefficient of linear expansion: about 4−5×10⁻⁶ K⁻¹)

### 2. Material of the Substrate 1

Mullite (thermal conductivity: 5 W·m⁻¹·K⁻¹; coefficient of linear expansion: 5.0−5.8×10⁻⁶ K⁻¹)

### 3. Material of the Cap 3

PYREX (thermal conductivity: 1.1 W·m⁻¹·K⁻¹; coefficient of linear expansion: 3.25×10⁻⁶ K⁻¹ 0-300° C.)

[Second Modification]

In any embodiment described above, the bonding step performed in forming the sealing structure 12 (i.e., Step 1-3 in the first embodiment; Step 2-3 in the second embodiment; Step 3-3 in the third embodiment; and Step 4-2 in the fourth embodiment), solder is used. In the bonding step, a sealing space 15 is provided. Nevertheless, the bonding is not limited to a method that uses solder, so long as the part involved can be heated and bonded together.

For example, thermosetting adhesive, glass frit or solid-phase diffusion of metal may be used in place of solder, to bond the parts. If thermosetting adhesive or glass frit is used, neither the first metal thin film 9 nor the second metal thin film 10 needs to be formed. If glass frit is used, outgases will hardly be generated. Hence, glass frit is preferred as bonding material for providing the sealing structure.

If glass frit is used, the first and second metal thin films 9 and 10 and, if necessary, the third and fourth metal thin films 13 and 14 will be used so that reliable bonding may be accomplished to provide a sealing structure. Solid-phase diffusion bonding of metal should preferably be performed to provide a sealing structure, because outgases will hardly be generated during the solid-phase diffusion bonding.

Further, solid-phase diffusion bonding of metal does not require any bonding agent such as thermosetting adhesive. Therefore it is not necessary to contemplate a method applying a bonding agent, an appropriate rate of supplying such an agent, or a method of preserving such an agent.

In the solid-phase diffusion bonding of metal, too, the first and second metal thin films 9 and 10 and, if necessary, the third and fourth metal thin films 13 and 14 may be used in order to perform reliable bonding may be accomplished to provide a sealing structure.

[Third Modification]

In the second embodiment, the size L₂ of the intermediate member 2 is greater than the size L₃ of the cap 3. To attain the same advantages as in the second embodiment, it suffices to make the intermediate member 2 larger than the substrate 1 or the cap 3, or both.

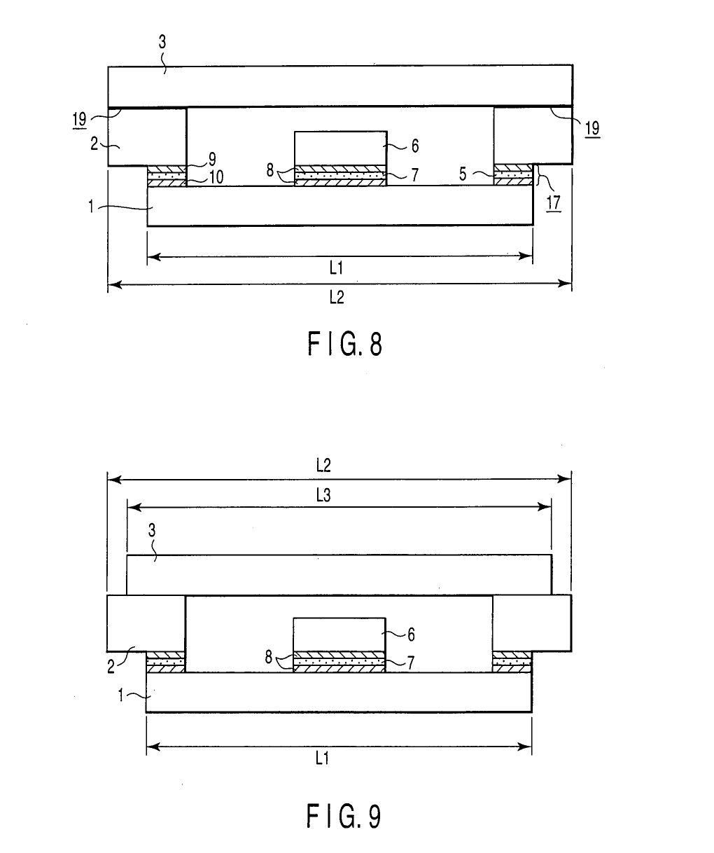

For example, the size L₂ of the intermediate member 2 may be greater than the size L₁ of the substrate 1 as shown in FIG. 8. Alternatively, the size L₂ of the intermediate member 2 may be greater than both the size L₁ of the substrate 1 and the size L₃ of the cap 3 as shown in FIG. 9. In either case, the same advantages can be attained as in the second embodiment.

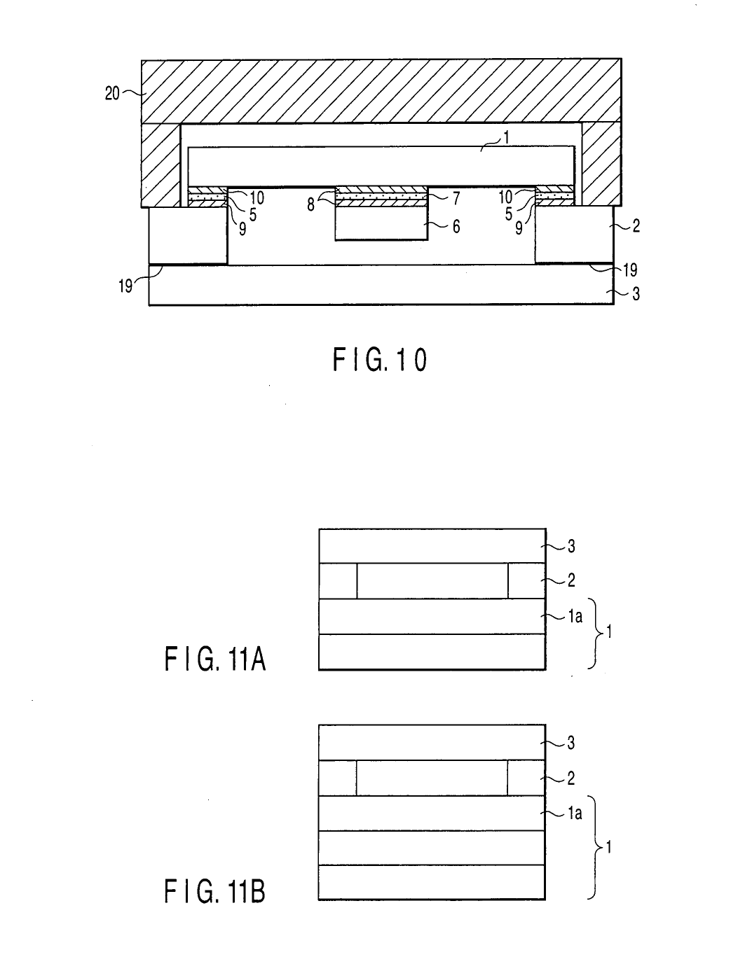

If the size L₂ of the intermediate member 2 is greater than the size L₁ of the substrate 1, Step 2-3 shown in FIG. 4 will become as shown in FIG. 10. That is, in the third modification, the intermediate member 2 has a part which the boding tool 20 can abut, as in the second embodiment. Thus, the bonding tool 20 can abut the intermediate member 2 as is illustrated in FIG. 10.

[Fourth Modification]

The technique of making the intermediate member 2 larger than the substrate 1 or the cap 3, or both may be applied to the third embodiment, the fourth embodiment, any modification described above, and any modification that will be described hereinafter.

[Fifth Modification]

The material of the cap 3 is not limited to glass. The cap 3 can be made of any material that serves to provide the sealing structure 12 described above. The cap 3 may be made of, for example, ceramics or plastics that transmit no light. If made of such ceramics or plastics, the cap 3 will have a high resistance to impacts than one made of glass, unless it is made of a special method.

The cap 3 may be made of plastic that transmit light, instead. In this case, the device 6 sealed in the sealing structure 12 can apply light into a space 16 outside the sealing structure 12, through the cap 3, and can receive light from the space 16 through the cap 3. The fifth modification can relatively increase the productivity of the cap 3, particularly if the cap 3 has an array of lenses or aspherical lenses.

### Sixth Embodiment

In the first to fourth embodiments, the die bonding of the device 6 and substrate 1 is not limited to die bonding using a solder layer 7. That is, the device 6 and the substrate 1 may be bonded by any other method, provided that the device 6 never comes off the substrate 1. Nonetheless, it is desired that outgases be hardly generated in the bonding step. If the device 6 is of such a type that may be degraded when heated, it is desirable to perform the bonding at a relatively low temperature.

[Seventh Modification]

In the first embodiment, a small light deflector is exemplified as device 6. The device 6 is not limited to a small light deflector, nevertheless. Instead, the device 6 may be, for example, a one-axis, two-axis or three-axis accelerometer, an angular accelerometer or the like, which is improved in performance or reliability when sealed in a space.

Further, the cap 3 may be made of light-transmitting material. Then, the device 6 can be, for example, a solid-state image sensing device (e.g., a CCD), a deformable mirror, or the like, which is improved in performance or reliability when sealed and which needs to emit and receive light into and from a space 16 outside the sealing structure 12.

[Eighth Modification]

The first to fourth embodiments are designed on the assumption that one device 6 is sealed in a sealing structure 12. Nonetheless, the number of devices 6 is not limited to one. A plurality of devices 6 may be sealed in the sealing structure. In this case, the devices 6 can be of different types. For example, a small light deflector and an accelerometer may be sealed in a sealing structure.

[Ninth Modification]

The first to fourth embodiments are designed on the assumption that the substrate 1 is a single layer. Instead, the substrate 1 may be composed of layers of different materials, as illustrated in FIG. 11A or FIG. 11B. In this case, the component layer 1a of the substrate 1, which contacts the intermediate layer 2, must have such a thermal conductivity that the intermediate member 2 has higher thermal conductivity than the substrate 1, which is a characterizing point of this invention. Further, the component layer 1a may be designed to have a specific dimensional relationship with the intermediate member 2.

In FIGS. 11A and 11B, the components other than the substrate 1, intermediate member 2 and cap 3 are not shown, in order to highlight the characterizing point of the present modification.

[Tenth Modification]

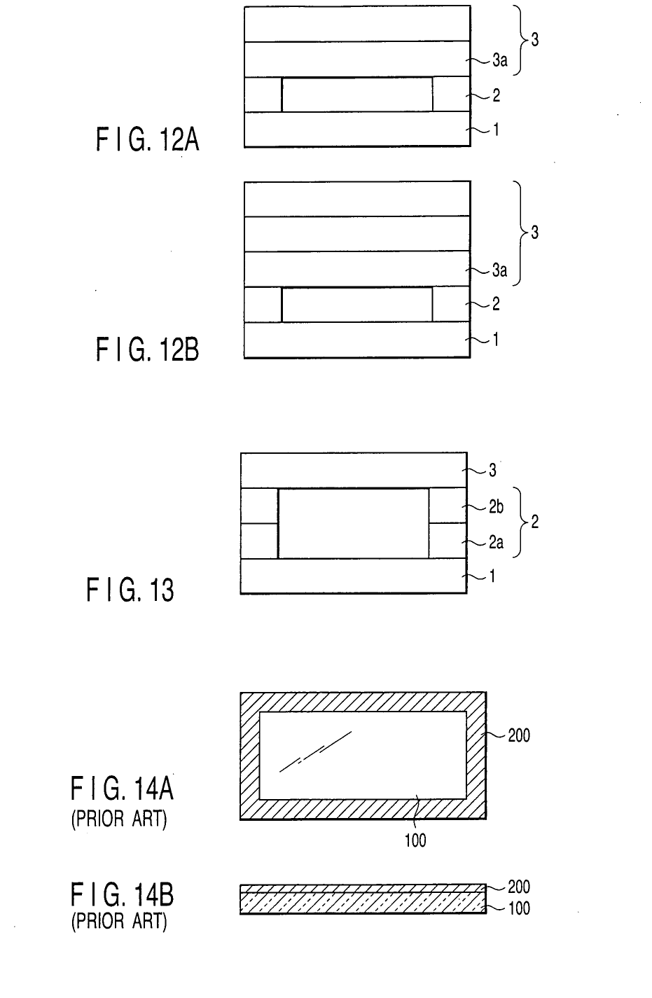

The first to fourth embodiments are designed on the assumption that the cap 3 is a single layer. Instead, the cap 3 may be composed of layers of different materials, as illustrated in FIG. 12A or FIG. 12B. In this case, the component layer 3a of the cap 3, which contacts the intermediate member 2, must have such a thermal conductivity that the intermediate member 2 has higher thermal conductivity than the cap 3, which is another characterizing point of this invention. Further, the component layer 3a may be designed to have a specific dimensional relationship with the intermediate member 2.

In FIGS. 12A and 12B, the components other than the substrate 1, intermediate member 2 and cap 3 are not shown, in order to highlight this characterizing point of the present modification.

[Eleventh Modification]

The first to fourth embodiments are designed on the assumption that the intermediate member 2 is a single layer. Instead, the intermediate member 2 may be composed of layers 2a and 2b of different materials, as illustrated in FIG. 13. In this case, the component layer 2a of the intermediate member 2, which contacts the substrate 1, must have such a thermal conductivity that the intermediate member 2 has higher thermal conductivity than the substrate 1, which is still another characterizing point of this invention.

In addition, the component layer 2b of the intermediate member 2, which contacts the cap 3, must have such a thermal conductivity that the intermediate member 2 has higher thermal conductivity than the cap 3, which is a further characterizing point of this invention.

The component layer 2a may be designed to have a specific dimensional relationship with the substrate 1. Similarly, the component layer 2b may be designed to have a specific dimensional relationship with the cap 3.

In FIG. 13, the components other than the substrate 1, intermediate member 2 and cap 3 are not shown, in order to highlight these characterizing points of the present modification.

[Twelfth Modification]

The solder layer 5 and the solder layer 5b can be made of any solder alloys available, provided that they can serve to provide the sealing structure 12 described above. In view of the environmental preservation, however, they should better be made of lead-free solder.

The solder layer 5 and the solder layer 5b should better be made of lead-free solder which has a lower melting point, rather than that of lead eutectic solder, particularly in the case where the device 6 may be degraded in performance when it is heated. Examples of the lead-free solder are solder of tin (Sn) and bismuth (Bi), tin-bismuth solder containing metal other than lead (Pb), such as silver (Ag), solder made of tin (Sn) and indium (In), or tin-indium solder containing metal other than lead (Pb), such as silver (Ag).

If the solder layer 5 and the solder layer 5b are made of such solder, the device 6 can be as desired, with suppression of the degradation in performance even if it is an electronic device, an MEMS device or the like, which may be degraded when heated and which should therefore be bonded at low temperatures.

[Thirteenth Modification]

The solder layer 7 can be made of any solder alloys available, too. In view of the environmental preservation, however, it should better be made of lead-free solder.

The solder layer 7 should better be made of lead-free solder, rather than lead eutectic solder, particularly in the case where the device 6 may be degraded in performance when it is heated. Examples of the lead-free solder are solder of tin (Sn) and bismuth (Bi), tin-bismuth solder containing metal other than lead (Pb), such as silver (Ag), solder made of tin (Sn) and indium (In), or tin-indium solder containing metal other than lead (Pb), such as silver (Ag).

If the solder layer 7 is made of such solder, the device 6 can be bonded as desired, with suppression of the degradation in performance even if it is an electronic device, a MEMS device or the like, which may be degraded when heated and which should therefore be bonded at low temperatures.

[Fourteenth Modification]

The first metal thin film 9, second metal thin film 10, third metal thin film 13 and fourth metal thin film 14 are not limited to single-layer films. Each may be, for example, a three-layer metal film composed of a chromium (Cr) layer, a nickel (Ni) layer and a gold (Au) layer.

[Fifteenth Modification]

The sealing space 15 may be filled with an atmosphere having oxygen concentration lower than that of air. (For example, the space 15 is filled with air virtually containing no oxygen.) This suppresses the degradation (oxidation) of the device 6.

The present modification enables the device 6 to be operated in a desired manner because of the suppression of the functional degradation by oxidation, even if the device 6 is the device which may not operate well in a vacuum or may not operate at all in a vacuum.

Further, the embodiments and modifications described above include various phases of the invention. The components disclosed herein may be combined in various ways to make various inventions.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A sealing structure having a sealing space provided by bonding a substrate and an intermediate member with a first bonding part and by bonding the intermediate member and a cap with a second bonding part,
wherein the intermediate member has a higher thermal conductivity than those of the substrate and the cap.

2. The sealing structure according to claim 1, wherein the cap is a member which transmits light.

3. The sealing structure according to claim 1, wherein the intermediate member has a size greater than that of at least one of the substrate and the cap.

4. The sealing structure according to claim 1, wherein the substrate, the intermediate member and the cap have substantially the same coefficient of linear expansion.

5. The sealing structure according to claim 1, wherein the cap is made of glass.

6. The sealing structure according to claim 5, wherein the intermediate member is made of silicon or Kovar.

7. The sealing structure according to claim 1, wherein at least one of the first and second bonding parts includes solder.

8. The sealing structure according to claim 7, wherein the solder is lead-free solder which has a lower melting point than that of lead eutectic solder.

9. The sealing structure according to claim 1, wherein at least one of the first and second bonding parts includes thermosetting adhesive.

10. The sealing structure according to claim 1, wherein at least one of the first and second bonding parts includes glass frit.

11. The sealing structure according to claim 1, wherein at least one of the first and second bonding parts is a bonding part formed by solid-phase diffusion bonding.

12. The sealing structure according to claim 1, wherein the sealing space is held at a pressure lower than the atmospheric pressure.

13. The sealing structure according to claim 1, wherein the sealing space is filled with an atmosphere having a lower oxygen concentration than that of air.

14. A method of manufacturing a sealing structure as described in claim 1, comprising:
a bonding step of bonding the cap, with the second bonding part, to a member which has been made by bonding the substrate and the intermediate member with the first bonding part.

15. A method of manufacturing a sealing structure as described in claim 1, comprising:
a bonding step of bonding the substrate, with the first bonding part, to a member which has been made by bonding the cap and the intermediate member with the second bonding part.

16. A method of manufacturing a sealing structure as described in claim 1, comprising:
a bonding step of bonding the substrate and the intermediate member with the first bonding part and bonding the intermediate member and the cap with the second bonding part.

17. The method according to claim 14, wherein, of the first and second bonding parts, one that is formed in the bonding step is made of any one of thermosetting adhesive, glass frit and solid-phase diffused material.

18. The method according to claim 15, wherein, of the first and second bonding parts, one that is formed in the bonding step is made of any one of solder, thermosetting adhesive, glass frit and solid-phase diffused material.

19. The method according to claim 16, wherein, of the first and second bonding parts, one that is formed in the bonding step is made of any one of solder, thermosetting adhesive, glass frit and solid-phase diffused material.
